(19) United States
(12) Patent Application Publication
(10) Pub. No.: US 2025/0254802 A1
(43) Pub. Date: Aug. 7, 2025

(54) CIRCUIT BOARD FIXATION DEVICE

(71) Applicant: Nanning FuLian FuGui Precision Industrial Co., Ltd., Nanning (CN)

(72) Inventor: YI-ZHAN LIN, New Taipei (TW)

(21) Appl. No.: 18/429,619

(22) Filed: Feb. 1, 2024

(51) Int. Cl. H05K 5/00; G01B 7/16

(52) U.S. Cl. CPC H05K 5/0026; G01B 7/18

(57) ABSTRACT

A circuit board fixation device comprising a casing, a fixing component, and a fixing rod. The wall surface of the casing is equipped with an array of multiple perforations. Fixing component are positioned on the casing, and the fixing component comprises a first driving rod and a limiting component. The two ends of the first driving rod are pivotally mounted on the casing and the side panels of the limiting component, respectively. One end of the fixing rod is pivotally mounted on the wall surface of the casing, while another end is equipped with a protrusion. When the circuit board is placed into the casing, the limiting component is moved to secure the circuit board, and then the protrusion is inserted into the groove on the side panel of the limiting component and into one of the corresponding multiple perforations.

### FIELD

The subject matter herein generally relates to an electronic device fixation component, particularly a circuit board fixation device with excellent securing effects.

### BACKGROUND

There are generally two main methods for fixing Peripheral Component Interconnect Express (PCI Express, PCIe) interface cards. One approach involves placing plastic latches on the I/O bracket at the front end of the PCIe card, using the rotation of the above mentioned plastic latches to secure the PCIe card. However, the drawback is that the rear end of the PCIe card is not securely fixed, and the plastic latches are prone to deformation, leading to the risk of PCIe cards becoming loose.

Another method for fixing PCIe cards involves adding a rotating plate cover to the rear of the expansion slot cage (riser cage), attaching foam padding to the cover where it contacts the PCIe card to prevent contact with electronic component on the PCIe card. During installation, the cover is rotated downward and locked in place. However, the downside is that due to the motion of the pivot structure, PCIe cards near the pivot point may be compressed, and this method only supports a single PCIe card specification.

Therefore, a circuit board fixation device that is easily assembled and disassembled, has a sturdy fixing structure, does not deform, and is applicable to various circuit boards with different specifications is needed.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a perspective view of an embodiment of the present disclosure;

FIG. 2 is an exploded view of a component of the embodiment of the present disclosure;

FIG. 3 is a cross-sectional schematic diagram of the embodiment of the present disclosure;

FIG. 4 is a block diagram of the embodiment of the present invention disclosure; and

FIG. 5, FIG. 6 and FIG. 7 are schematic diagrams illustrating consecutive usage states of the embodiment of the present invention disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one”.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to;” it specifically indicates open-ended inclusion or membership in the so-described combination, group, series, and the like.

The present invention is a circuit board fixation device designed for mounting circuit boards. The circuit board fixation device is used to install circuit boards in electronic devices, thereby expanding the performance of electronic devices. Electronic devices can include servers or computers, and the circuit boards can be Peripheral Component Interconnect Express (PCI Express, PCIe) cards used to connect processors, graphics cards, hard drives, network cards, and other essential components in electronic devices, providing high-speed data transmission and other functions.

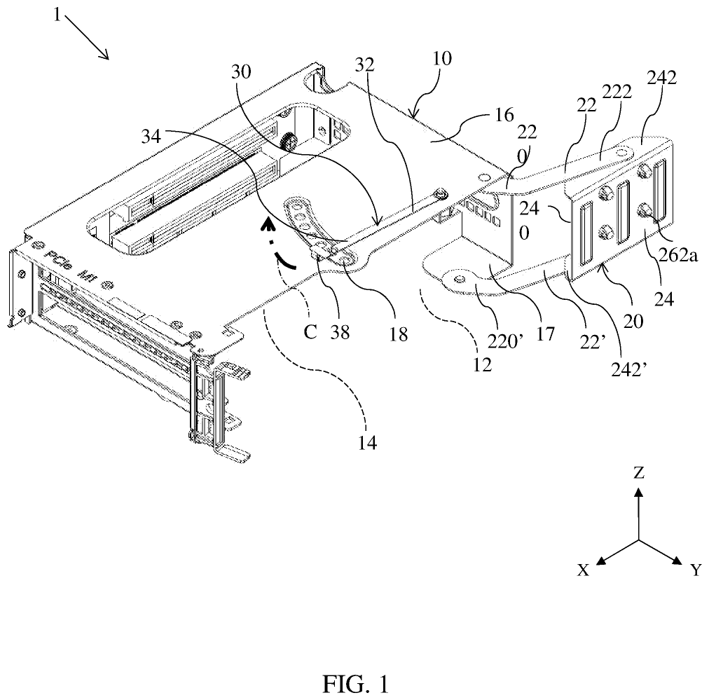

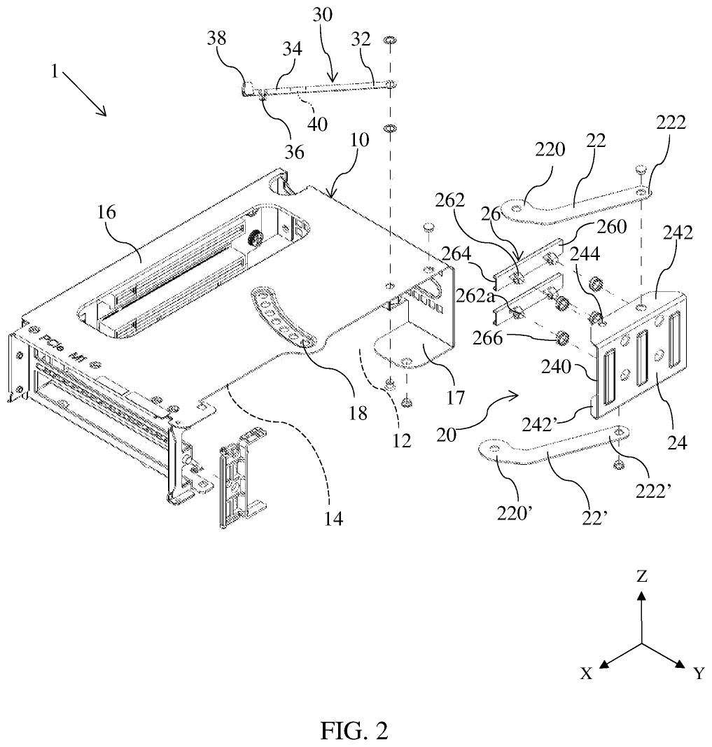

Please refer to FIG. 1 to FIG. 3 to illustrate the structure of a circuit board fixation device 1 in this embodiment. The circuit board fixation device 1 comprising a casing 10, a fixing component 20, and a fixing rod 30. The casing 10 has an opening 12, which connects to a fixed space 14 inside the casing 10. In this embodiment, the casing 10 is a rectangular prism. A wall surface 16 of the casing 10 is oriented along the Y-axis and is perpendicular to the opening 12. A mounting plate 17 is also oriented along the Y-axis and is perpendicular to the opening 12, with the mounting plate 17 placed opposite to the wall surface 16. Multiple perforations 18 are arranged on the wall surface 16. The multiple perforations 18 are gradually spaced away from the opening 12 along the wall surface 16, and they are arranged in spaced intervals along a curved path C. In this embodiment, the second end 34 of the fixing rod 30 moves along a curved path C. The multiple perforations 18 are spaced along the curved path C.

The fixing component 20 is positioned on the casing 10. The fixing component 20 comprising a first driving rod 22, a second driving rod 22′, a limiting component 24, and at least one fixing guide rail 26. The first driving rod 22 and the second driving rod 22′ are set on the casing 10, and the limiting component 24 connects the first driving rod 22 and the second driving rod 22′. The limiting component 24 comprises a limiting plate 240, a first side plate 242, and a second side plate 242′. A groove 244 is set on the first side plate 242. In this embodiment, the limiting plate 240 can be rectangular. The limiting plate 240 is vertically positioned relative to the first side plate 242, meaning the limiting plate 240 is oriented along the Z-axis and is perpendicular to the first side plate 242. The second side plate 242′ is oriented along the Z-axis, positioned opposite the first side plate 242, and the second side plate 242′ is also oriented along the Y-axis and is perpendicular to the limiting plate 240.

The fixed guide rail 26 is positioned on the limiting plate 240. The fixed guide rail 26 extends along the X-axis and is installed on the limiting plate 240. The fixed guide rail 26 comprises a body 260, at least one fixed protrusion 262, a guiding slot 264, and at least one elastic element 266. The fixed protrusion 262 is placed on one side of the body 260, and it passes through the limiting plate 240 to secure the body 260 to the limiting plate 240. In this embodiment, the fixed protrusion 262 passing through the end of the limiting plate 240 is further provided with a hook 260a, which can prevent the fixed protrusion 262 from detaching from the limiting plate 240. The guiding slot 264 is located on the body 260 and is positioned opposite the side where the fixed protrusion 262 is located. In this embodiment, the guiding slot 264 conforms to the shape of the circuit board to achieve the function of securing and limiting the position of the circuit board. The elastic element 266 is fitted on the fixed protrusion 262 and is positioned between the body 260 and the limiting plate 240. In this embodiment, the elastic element 266 is a spring.

In this embodiment, the first end 220′ of the second drive rod 22′ is pivotally mounted at the position of the mounting plate 17, separated from the first end 220 of the first drive rod 22, and is not on the same Z-axis straight line, being arranged in a staggered manner. The second end 222′ of the second drive rod 22′ is pivotally mounted at the position of the side plate 240′, not on the same Z-axis straight line as the first drive rod 22 is pivotally mounted on the side plate 240, being arranged in a staggered manner. If the pivot of the first drive rod 22 and the second drive rod 22′ is on the same Z-axis straight line without staggered placement, the limiting member 24 will rotate due to the lack of freedom to restrict rotation. However, in this embodiment, the offset between the upper and lower positions of the first drive rod 22 and the second drive rod 22′ can restrict the freedom of rotation due to the structure, allowing the supporting surface of the limiting member 24 to maintain horizontal movement in the XY plane, achieving parallel movement in the XY plane. At the same time, the structure of the first drive rod 22 and the second drive rod 22′ is the same, allowing interchangeable installation to reduce factory assembly errors.

The fixing rod 30 has a relative first end 32 and a second end 34. The first end 32 of the fixing rod 30 is pivotally mounted on the wall surface 16 of the casing 10. In this embodiment, the fixing rod 30 is positioned on the wall surface 16 on the same surface as the perforations 18. The first end 32 of the fixing rod 30 can be fixed to the wall surface 16 by a riveting process. The second end 34 of the fixing rod 30 is equipped with a protrusion 36 that extends along the Z-axis, intended to pass through one of the perforations 12 on the casing 10 and be fixed in the groove 244 of the limiting member 24, achieving the function of fixing the limiting member 24. The second end 34 of the fixing rod 30 is further equipped with a handle 38, and the handle 38 is positioned opposite to the protrusion 36 on another side and protrusion 36 extends along the Z-axis. The fixing rod 30 can be an elastic and electrically conductive fixing rod, and the material of the fixing rod 30 can be an electrically conductive metal, such as iron.

In addition to the above structure, as shown in FIG. 1 to FIG. 4, the circuit board fixation device 1 in this embodiment further comprises a deformation sensor 40 and a controller 42. In this embodiment, the deformation sensor 40 has a sheet-like structure. The deformation sensor 40 is placed on the fixing rod 30 and is signal-connected to the controller 42 to sense whether the fixing rod 30 undergoes deformation and transmit the detection result to the controller 42. In this embodiment, the deformation sensor 40 can be a strain gauge, and the controller 42 can be a computer with a bulb, light-emitting diode (LED), speaker, or screen. The controller 42 can be an external device.

The strain gauge utilizes the piezoresistive effect, where the resistance changes when an object deforms. In this embodiment, the deformation sensor 40 is placed on the fixing rod 30, and since the fixing rod 30 is made of an elastic and electrically conductive material, when the deformation sensor 40 detects deformation of the fixing rod 30, it generates a deformation signal to the controller 42. The controller 42 can then generate a warning signal based on the deformation signal. The controller 42 is equipped with a bulb, light-emitting diode (LED), speaker, or screen, and when the warning signal is generated, the controller 42 can control the bulb or LED to flash, display a message on the screen, or activate the speaker to produce a warning sound, alerting the user.

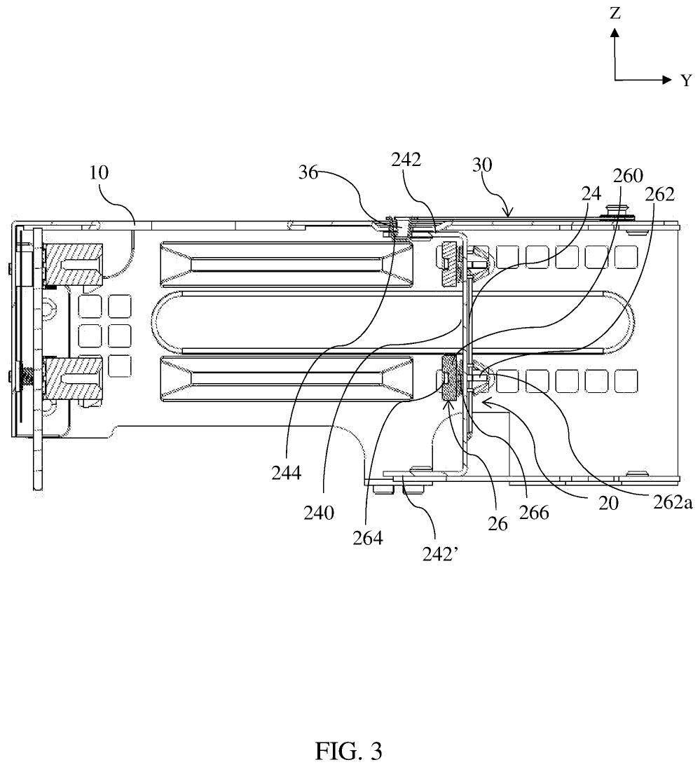

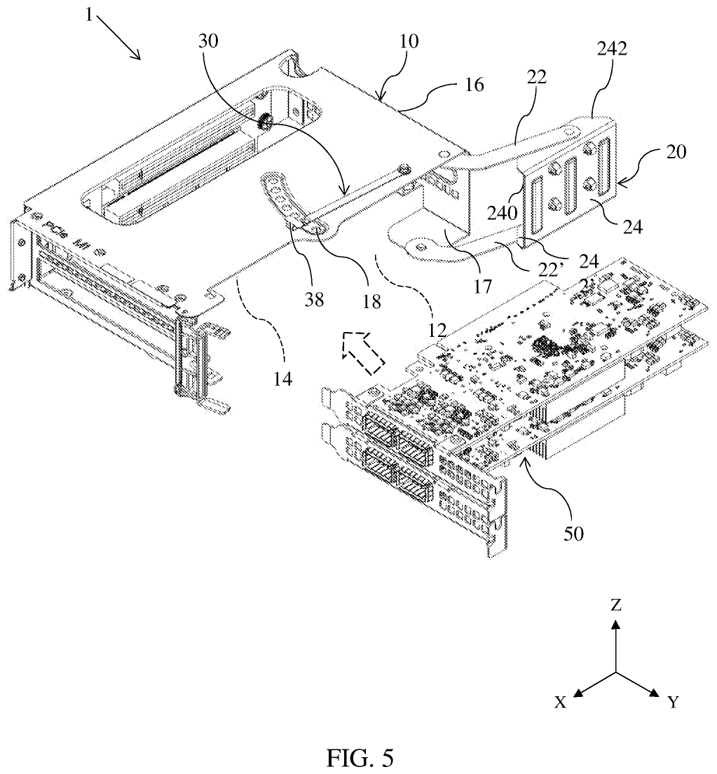

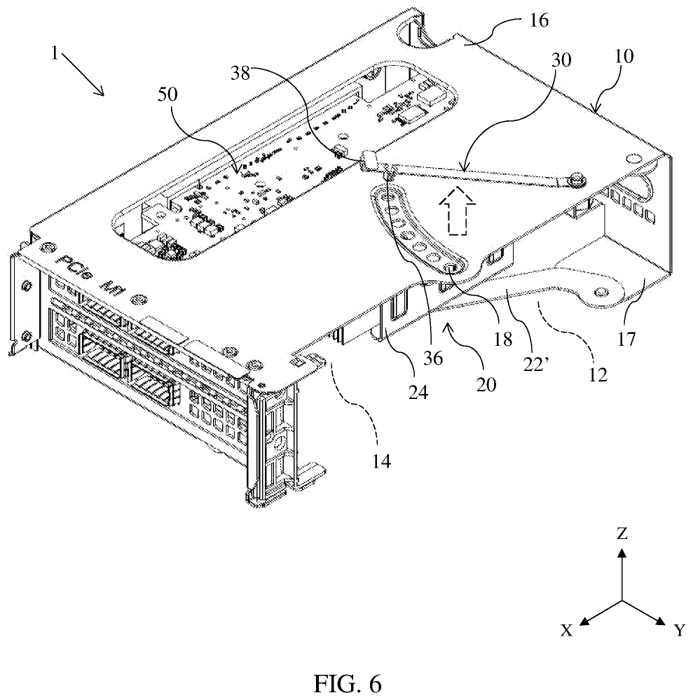

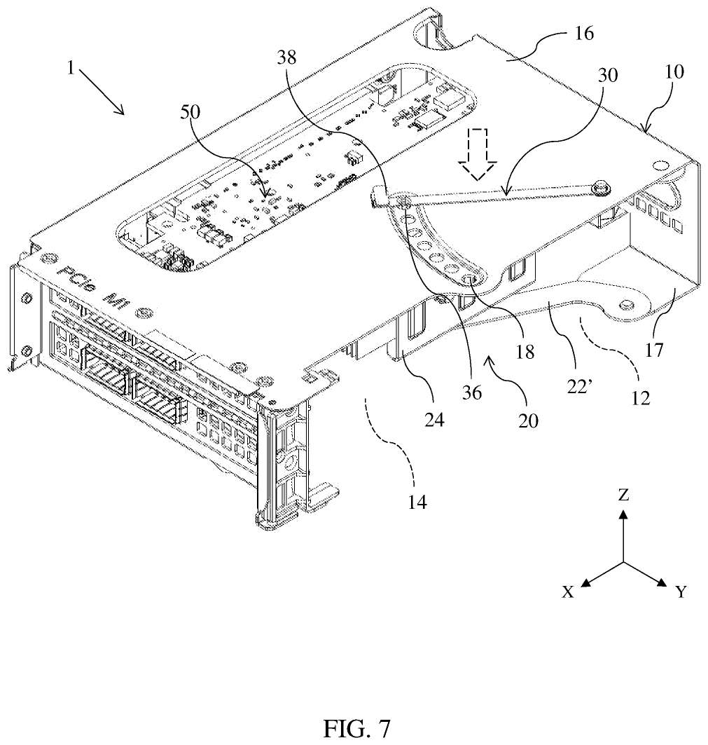

After explaining the structure of the circuit board fixation device 1 in this embodiment, please refer to FIG. 5 to FIG. 7 to illustrate the usage state of installing the circuit board with the circuit board fixation device 1. In this embodiment, a circuit board, such as a Peripheral Component Interconnect Express (PCIE) card. Please refer to FIG. 5, where the circuit board 50 is placed into the fixed space 14 through the opening 12. Next, please refer to FIG. 6, and in conjunction with FIG. 3, lift the fixing rod 30 by the handle 38 to move the protrusion 36 away from the perforation 18. Then, push the fixing assembly 20 into the fixed space 14 until the circuit board 50 is engaged with the guiding slot 264 of the fixed guide rail 26. Since the guiding slot 264 matches the shape of the circuit board 50, it effectively restricts and supports the circuit board 50, preventing it from bending. The placement of the elastic member 266 serves as a buffer and addresses manufacturing and assembly tolerances, ensuring effective contact between the fixed guide rail 26 and the circuit board 50.

Next, please refer to FIG. 7 and FIG. 3. Adjust the limiting component 24 to engage the circuit board 50 with the guiding slot 264, aligning the groove 244 with one of the perforations 18. By doing so, the fixing rod 30 can be adjusted, allowing the protrusion 36 to pass through the groove 244 and the corresponding one of the perforations 18. This action locks the position of the limiting component 24, thereby securing the circuit board 50 in place.

This embodiment is equipped with multiple perforations 18 to achieve the effect of securing circuit boards 50 of various specifications. Taking the example of a PCIE card, if the PCIE card is of a low-profile specification, which is a smaller-sized PCIE card, the protrusion 36 is engaged with the perforation 18 furthest from the opening 12. If the PCIE card is of a full-height specification, which is a larger-sized PCIE card, the protrusion 36 is engaged with the perforation 18 closest to the opening 12. Therefore, the circuit board fixing device 1 of this embodiment can accommodate various specifications of circuit boards.

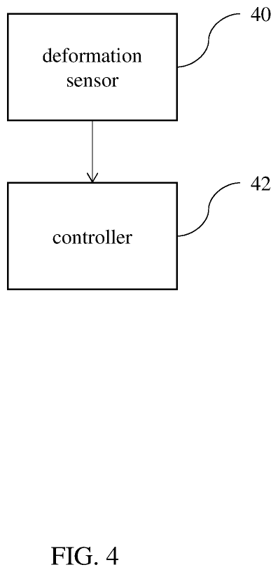

Please refer to FIG. 7 and FIG. 4. If the user fails to securely place the protrusion 36 into the perforation 18 while fixing the circuit board 50, it leads to deformation of the fixing rod 30. At this point, the deformation sensor 40 detects the deformation of the fixing rod 30, generating the deformation signal to the controller 42. Then the controller 42 generate a warning signal based on the deformation signal. The controller 42 can alert the user to adjust the fixing rod 30 through flashing lights on a bulb or LED, displaying a message on the screen, or emitting a warning sound through the speaker, among other methods.

In summary, the present invention provides excellent parallel guiding and fastening effects, and is capable of accommodating various circuit board specifications. Additionally, when the fixing rod is not securely in place, a warning can be issued to remind the user of ineffective circuit board fixation.

Many details are often found in the relevant art and many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A circuit board fixation device comprising:
a casing defining an opening, multiple perforations a wall surface of the casing and a fixed space therein with, the opening providing communication between the fixed space and the multiple perforations;
a fixing component positioned on the casing, the fixing component comprising:
a first driving rod, a first end of the first driving rod pivotally mounted on the casing near the opening;
a limiting component comprising a limiting plate and a first side plate defining a groove, the first side plate vertically positioned on the limiting plate, and a second end of the first driving rod pivotally mounted on the first side plate;
a fixing rod, a first end of the fixing rod pivotally mounted on the wall surface of the casing, and a second end of the fixing rod comprises a protrusion which is inserted into one of the multiple perforations, secured in the groove thereby fixing the limiting component to the casing.

2. The device of claim 1, wherein the fixing component further comprises at least one fixing guide rail on the limiting plate, the fixing guide rail comprises:
a body installed on the limiting plate;
at least one fixed protrusion located on a side of the body, extending through the limiting plate and fixed on the limiting plate; and
a guiding slot on the body, positioned opposite a side where the fixed protrusion is located.

3. The device of claim 2, wherein the fixing guide rail further comprises an elastic element, the elastic element is encased on the fixed protrusion and positioned between the body and the limiting plate.

4. The device of claim 3, wherein the elastic element is a spring.

5. The device of claim 2, wherein the fixed protrusion further comprises a hook, the hood is positioned at an end of the fixed protrusion where the fixed protrusion extends through the limiting plate.

6. The device of claim 1, wherein the multiple perforations are arranged in a spaced manner.

7. The device of claim 6, wherein the second end of the fixing rod moves along a curved path.

8. The device of claim 7, wherein the multiple perforations are further arranged at intervals along the curved path.

9. The device of claim 1, wherein the fixing rod is elastic and electrically conductive.

10. The device of claim 9 further comprising a deformation sensor installed on the fixing rod, the deformation sensor emits a deformation signal when the deformation sensor detects the fixing rod is deformed.

11. The device of claim 10 further comprising a controller connected to the deformation sensor, the controller configured to receive the deformation signal and generate a warning signal based on the deformation signal.

12. The device of claim 10, wherein the deformation sensor is a strain gauge.

13. The device of claim 1, wherein the second end of the fixing rod comprises a handle, and the handle is positioned opposite to the protrusion on another side of the protrusion.

14. The device of claim 1, wherein the limiting component further comprises a second side plate, the second side plate is positioned on the limiting plate and opposite to the first side plate; the fixing component further comprises a second driving rod, where a first end of the second driving rod is pivotally mounted on the casing near the opening, and the second driving rod is positioned opposite to the first driving rod, the second end of the second driving rod is pivotally mounted on the second side plate.

15. The device of claim 14, wherein the casing further comprises a mounting plate, the mounting plate is positioned opposite to the wall surface, the second driving rod is pivotally mounted on the mounting plate.

16. The device of claim 14, wherein the first driving rod is offset from the second driving rod.
